(19) United States
(12) Patent Application Publication
(10) Pub. No.: US 2026/0025106 A1
(43) Pub. Date: Jan. 22, 2026

(54) DOHERTY AMPLIFIER CIRCUIT

(71) Applicant: Murata Manufacturing Co., Ltd., Nagaokakyo-shi (JP)

(72) Inventor: Shohei IMAI, Nagaokakyo-shi (JP)

(21) Appl. No.: 19/342,748

(22) Filed: Sep. 29, 2025

Related U.S. Application Data
(63) Continuation of application No. PCT/JP2024/005711, filed on Feb. 19, 2024.

(30) Foreign Application Priority Data
Apr. 12, 2023 (JP) 2023-065150

(51) Int. Cl. H03F 1/02; H03F 3/24

(52) U.S. Cl. CPC H03F 1/0288; H03F 3/245; H03F 2200/451

(57) ABSTRACT

A Doherty amplifier circuit capable of supporting high-speed communication is attained. The Doherty amplifier circuit includes a carrier amplifier that amplifies a first high frequency signal corresponding to an input high frequency signal, a driver-stage peak amplifier that amplifies a second high frequency signal having a predetermined phase relationship with a phase of the first high frequency signal, a power-stage peak amplifier that receives an outputted from the driver-stage peak amplifier, and a drive-level detection circuit that detects a drive level of the carrier amplifier. The driver-stage peak amplifier includes a first amplifier and a second amplifier. A bias based on a drive level signal indicating the drive level detected by the drive-level detection circuit is supplied to one of the first amplifier and the second amplifier. A bias corresponding to the input high frequency is supplied to the other one of the first amplifier and the second amplifier.

### CROSS REFERENCE TO RELATED APPLICATION

This is a continuation of International Application No. PCT/JP2024/005711 filed on Feb. 19, 2024 which claims priority from Japanese Patent Application No. 2023-065150 filed on Apr. 12, 2023. The contents of these applications are incorporated herein by reference in their entireties.

### BACKGROUND OF THE DISCLOSURE

### Field of the Disclosure

The present disclosure relates to a Doherty amplifier circuit.

### Description of the Related Art

As highly efficient power amplifier circuits, Doherty amplifier circuits have been known. A typical Doherty amplifier circuit is configured such that a carrier amplifier that operates irrespective of the power level of an input signal, and a peak amplifier that is turned off when the power level of an input signal is small and turned on when the power level of an input signal is large are connected in parallel. With this configuration, in the case where the power level of a high frequency input signal is large, the carrier amplifier operates with saturation maintained at a saturated output power level. Thus, compared to ordinary power amplifier circuits, Doherty amplifier circuits can achieve improved efficiency.

In U.S. Patent Application Publication No. 2020/0028472, a technique for controlling a bias of a peak amplifier is described. The technique described in U.S. Patent Application Publication No. 2020/0028472 involves detecting saturation of a carrier amplifier based on an output signal from the carrier amplifier and controlling a bias circuit for the peak amplifier based on a detection signal.

### BRIEF SUMMARY OF THE DISCLOSURE

In the Doherty amplifier circuit described in U.S. Patent Application Publication No. 2020/0028472, control is implemented by inputting to the bias circuit a result obtained by adding the detection signal and another signal by using an adder. In this case, control that follows the change speed of the output signal from the carrier amplifier cannot be performed satisfactorily, and a large distortion occurs in an amplifier. Therefore, a Doherty amplifier circuit capable of supporting high-speed communication cannot be attained.

The present disclosure has been made in view of the points mentioned above, and a possible benefit of the present disclosure is to provide a Doherty amplifier circuit capable of supporting high-speed communication.

A Doherty amplifier circuit according to an aspect of the present disclosure includes a carrier amplifier that amplifies a first high frequency signal corresponding to an input high frequency signal, a driver-stage peak amplifier that amplifies a second high frequency signal having a predetermined phase relationship with a phase of the first high frequency signal, a power-stage peak amplifier that receives an output from the driver-stage peak amplifier, and a drive-level detection circuit that detects a drive level of the carrier amplifier. The driver-stage peak amplifier includes a first amplifier and a second amplifier. A bias based on a drive level signal indicating the drive level detected by the drive-level detection circuit is supplied to one of the first amplifier and the second amplifier. A bias corresponding to the input high frequency signal is supplied to the other one of the first amplifier and the second amplifier.

According to the present disclosure, a Doherty amplifier circuit capable of supporting high-speed communication can be attained.

### BRIEF DESCRIPTION OF THE SEVERAL VIEWS OF THE DRAWINGS

FIG. 1 is a diagram illustrating a configuration of a Doherty amplifier circuit according to a first embodiment.

FIG. 2 is a diagram illustrating an example of a configuration of a drive-level detection circuit in FIG. 1.

FIG. 3 is a diagram illustrating a specific example of a configuration of the drive-level detection circuit in FIG. 1.

FIG. 4 is a diagram illustrating a configuration of a Doherty amplifier circuit according to a second embodiment.

FIG. 5 is a diagram illustrating a configuration of a Doherty amplifier circuit according to a third embodiment.

FIG. 6 is a diagram illustrating a configuration of a Doherty amplifier circuit according to a fourth embodiment.

FIG. 7 is a diagram illustrating a configuration of a Doherty amplifier circuit according to a fifth embodiment.

FIG. 8 is a diagram illustrating a configuration of a Doherty amplifier circuit according to a sixth embodiment.

FIG. 9 is a diagram illustrating a configuration of a Doherty amplifier circuit according to a seventh embodiment.

### DETAILED DESCRIPTION OF THE DISCLOSURE

Hereinafter, embodiments of the present disclosure will be described in detail with reference to the drawings. In the description of each embodiment provided below, component parts that are the same as or equivalent to those in other embodiments will be denoted by the same signs, and description of those component parts will be simplified or omitted. The present disclosure is not intended to be limited by the embodiments. Furthermore, component elements in the embodiments include those which can be easily replaced by those skilled in the art or those which are substantially the same. Configurations described below can be combined in a desired manner. Omission, replacement, or change can be made to a configuration without departing from the gist of the present disclosure. In the second and subsequent embodiments, description of features that are in common with the first embodiment will be omitted in an appropriate manner and different features will be described. In particular, similar operational effects achieved by similar configurations will not be described in each embodiment.

### First Embodiment

(Overall configuration)

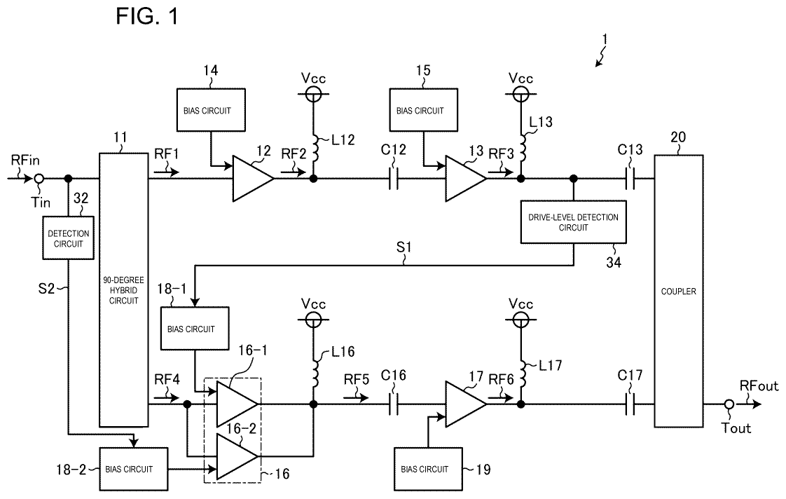

FIG. 1 is a diagram illustrating a configuration of a Doherty amplifier circuit according to a first embodiment. In FIG. 1, a Doherty amplifier circuit 1 according to the first embodiment includes an input terminal Tin, a 90-degree hybrid circuit 11, an initial-stage (driver-stage) carrier amplifier 12, a final-stage (power-stage) carrier amplifier 13, bias circuits 14 and 15, an initial-stage peak amplifier 16, a final-stage peak amplifier 17, bias circuits 18-1, 18-2, and 19, a coupler 20, a drive-level detection circuit 34, a detection circuit 32, and an output terminal Tout. The peak amplifier 16 includes a first amplifier 16-1 and a second amplifier 16-2.

The 90-degree hybrid circuit 11 divides an input signal RFin, which is a high frequency signal, into high frequency signals RF1 and RF4 with a phase difference of approximately 90 degrees, outputs the high frequency signal RF1 to the carrier amplifier 12, and outputs the high frequency signal RF4 to the peak amplifier 16. Since there is a phase difference of approximately 90 degrees between the high frequency signals RF1 and RF4, it can be regarded that the high frequency signal RF4 is a signal having a predetermined phase relationship with the phase of the high frequency signal RF1. “Approximately 90 degrees” not only represents a phase of 90 degrees but also includes phases of 90 degrees plus or minus 45 degrees. The input signal RFin corresponds to an “input high frequency signal” in the present disclosure. The high frequency signal RF1 corresponds to a “first high frequency signal” in the present disclosure. The high frequency signal RF4 corresponds to a “second high frequency signal” in the present disclosure.

It is illustrated that the phase of the high frequency signal RF4 is delayed from the high frequency signal RF1 by 90 degrees. It is illustrated that the power of the high frequency signal RF1 and the power of the high frequency signal RF4 are the same.

The bias circuit 14 supplies a bias to the carrier amplifier 12. The bias circuit 15 supplies a bias to the carrier amplifier 13. The carrier amplifier 12 outputs a high frequency signal RF2, which is obtained by amplifying the high frequency signal RF1, to the carrier amplifier 13. The carrier amplifier 13 outputs a high frequency signal RF3, which is obtained by amplifying the high frequency signal RF2, to the coupler 20.

A power supply Vcc is connected to an output side of the carrier amplifier 12 with an inductor L12 interposed therebetween. A capacitor C12 is provided between the carrier amplifier 12 and the carrier amplifier 13. A DC component of the high frequency signal RF2 is cut by the capacitor C12.

A power supply Vcc is connected to an output side of the carrier amplifier 13 with an inductor L13 interposed therebetween. A capacitor C13 is provided between the carrier amplifier 13 and the coupler 20. A DC component of the high frequency signal RF3 is cut by the capacitor C13.

The drive-level detection circuit 34 receives the high frequency signal RF3. The drive-level detection circuit 34 detects the drive level (operation level) of the carrier amplifier 13 based on the high frequency signal RF3. The drive-level detection circuit 34 generates a signal indicating the drive level (hereinafter, may be referred to as a drive level signal) S1. The signal S1 is inputted to the bias circuit 18-1. The signal S1 is a signal for setting a bias point of the first amplifier 16-1. The signal S1 may be a signal (inversion signal) that changes in a complementing manner with respect to the drive level of the carrier amplifier 13. The bias circuit 18-1 supplies a bias to the first amplifier 16-1 based on the signal S1.

The detection circuit 32 receives the input signal RFin, which is a high frequency signal inputted to the input terminal Tin. The detection circuit 32 outputs a signal S2 based on the input signal RFin. The signal S2 is a baseband signal corresponding to the strength of the input signal RFin. The signal S2 is inputted to the bias circuit 18-2. The signal S2 is a signal for setting a bias point of the second amplifier 16-2. The bias circuit 18-2 supplies a bias to the second amplifier 16-2 based on the signal S2.

The peak amplifier 16 outputs a high frequency signal RF5, which is obtained by amplifying the high frequency signal RF4, to the peak amplifier 17. The first amplifier 16-1 and the second amplifier 16-2 are connected in parallel. Thus, inputs of the first amplifier 16-1 and the second amplifier 16-2 are connected to each other. The high frequency signal RF4 is inputted to the first amplifier 16-1 and the second amplifier 16-2. Furthermore, outputs of the first amplifier 16-1 and the second amplifier 16-2 are connected to each other. An output signal from the first amplifier 16-1 and an output signal from the second amplifier 16-2 are added to form the high frequency signal RF5.

The bias circuit 19 supplies a bias to the peak amplifier 17. The peak amplifier 17 outputs a high frequency signal RF6, which is obtained by amplifying the high frequency signal RF5, to the coupler 20.

A power supply Vcc is connected to an output side of the peak amplifier 16 with an inductor L16 interposed therebetween. A capacitor C16 is provided between the peak amplifier 16 and the peak amplifier 17. A DC component of the high frequency signal RF5 is cut by the capacitor C16.

A power supply Vcc is connected to an output side of the peak amplifier 17 with an inductor L17 interposed therebetween. A capacitor C17 is provided between the peak amplifier 17 and the coupler 20. A DC component of the high frequency signal RF6 is cut by the capacitor C17.

The coupler 20 combines the high frequency signal RF3 and the high frequency signal RF6 together. In the first embodiment, the coupler 20 is a phase shifter. However, the coupler 20 is not necessarily a phase shifter in the present disclosure. The coupler 20 delays the phase of the high frequency signal RF3 by 90 degrees. The coupler 20 outputs, as an output signal RFout, which is a high frequency signal, the sum of the high frequency signal RF3 whose phase has been delayed by 90 degrees and the high frequency signal RF6, from the output terminal Tout.

### (Configuration of Drive-Level Detection Circuit)

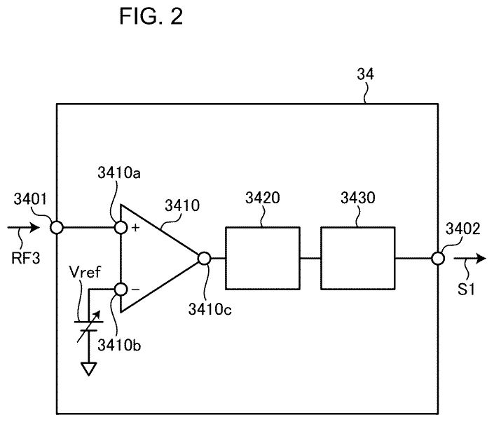

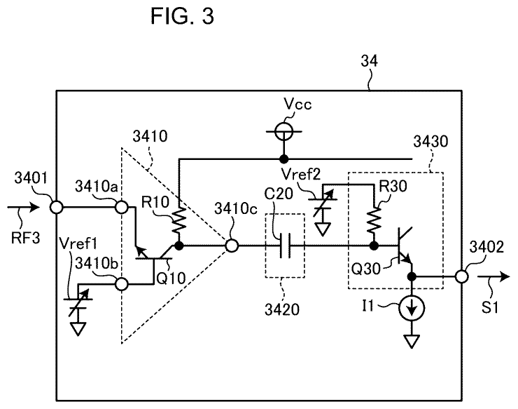

Next, a configuration of the drive-level detection circuit 34 will be described specifically with reference to FIGS. 2 and 3. FIG. 2 is a diagram illustrating an example of a configuration of the drive-level detection circuit 34 in FIG. 1. FIG. 3 is a diagram illustrating a specific example of the configuration of the drive-level detection circuit 34 in FIG. 1.

An overview of the configuration of the drive-level detection circuit 34 will be described with reference to FIG. 2. As illustrated in FIG. 2, the drive-level detection circuit 34 includes an input terminal 3401 that is electrically connected to an output terminal of the carrier amplifier 13 and a detection terminal 3402 for detecting the signal level of the output of the carrier amplifier 13.

The drive-level detection circuit 34 includes, for example, the input terminal 3401, the detection terminal 3402, a comparison unit 3410, a DC removal unit 3420, and a detection unit 3430.

The input terminal 3401 is, for example, a terminal that is electrically connected to the output terminal of the carrier amplifier 13.

The detection terminal 3402 is, for example, a terminal that is electrically connected to an input terminal of the bias circuit 18-1. That is, the detection terminal 3402 is a terminal for inputting the signal level of the output of the carrier amplifier 13 to the bias circuit 18-1.

The comparison unit 3410 is, for example, a comparator and outputs, based on a reference voltage inputted to one input terminal as a boundary, an output signal corresponding to a voltage inputted to another input terminal.

Specifically, the comparison unit 3410 includes, for example, two input terminals 3410a and 3410b, and an output terminal 3410c. The input terminal 3410a of the comparison unit 3410 is electrically connected to the output terminal of the carrier amplifier 13, and the input terminal 3410b of the comparison unit 3410 is electrically connected to a reference voltage Vref. The output terminal 3410c of the comparison unit 3410 is electrically connected to the DC removal unit 3420, which will be described below.

The DC removal unit 3420 removes a DC component of an output signal outputted from the comparison unit 3410. That is, the DC removal unit 3420 allows a high frequency component in the output signal to pass through.

For example, a first terminal of the DC removal unit 3420 is electrically connected to the output terminal 3410c of the comparison unit 3410, and a second terminal of the DC removal unit 3420 is electrically connected to the detection unit 3430, which will be described below.

The detection unit 3430 detects an output signal from which a DC component has been removed by the DC removal unit 3420. The detection unit 3430 converts the output signal into a DC component and outputs the DC component as the signal S1.

An input terminal of the detection unit 3430 is electrically connected to the second terminal of the DC removal unit 3420. An output terminal of the detection unit 3430 is electrically connected to the detection terminal 3402.

As described above, in the drive-level detection circuit 34, by removing a DC component of an output signal outputted from the comparison unit 3410, a delay in the response time of the comparison unit 3410 caused by the DC component can be reduced or eliminated. Furthermore, by removing a DC component of an output signal outputted from the comparison unit 3410, the drive-level detection circuit 34 can suppress variations in a bias point of the detection unit 3430.

In contrast, in the saturation detection circuit in U.S. Patent Application Publication No. 2020/0028472, it requires much time to stabilize a DC component of an output signal outputted from a comparator. In other words, since a DC component outputted from the comparator affects the operation of the comparator itself in the saturation detection circuit, it requires much time to stabilize a response.

That is, the drive-level detection circuit 34 is configured to remove a DC component of an output signal from the comparison unit 3410, and this configuration prevents the output signal from affecting the operation of the comparison unit 3410. Thus, compared to the related art, the drive-level detection circuit 34 achieves a remarkable effect of being able to reduce or eliminate the delay in the response time of the comparison unit 3410.

Next, an example of a specific configuration of the drive-level detection circuit 34 will be described with reference to FIG. 3.

As illustrated in FIG. 3, the comparison unit 3410 includes, for example, a transistor Q10. An emitter of the transistor Q10 is electrically connected to the output terminal (for example, a collector) of the carrier amplifier 13. A base of the transistor Q10 is electrically connected to a reference voltage Vref1. A collector of the transistor Q10 is electrically connected to the first terminal of the DC removal unit 3420. The collector of the transistor Q10 is electrically connected to a power supply Vcc with a resistor R10 interposed therebetween.

The DC removal unit 3420 removes a DC component, which is outputted from the comparison unit 3410. The DC component requires, due to the influence of an operation of the comparison unit 3410 (operation of the transistor Q10), much time to become stable. Then, the DC removal unit 3420 outputs a high frequency component to be used as a detection signal to the detection unit 3430. That is, the DC removal unit 3420 isolates the comparison unit 3410 from the detection unit 3430 in a DC manner so that the DC component that requires much time to become stable does not affect the detection unit 3430. As described above, the drive-level detection circuit 34 removes the DC component that requires much time to become stable, and uses a resultant high frequency component as a detection signal. Thus, a delay in response, which occurs in the case where a DC component outputted from the comparison unit 3410 is used as a detection signal, can be resolved.

The DC removal unit 3420 includes, for example, a capacitor C20. A first terminal of the capacitor C20 is electrically connected to the collector of the transistor Q10, and a second terminal of the capacitor C20 is electrically connected to the detection unit 3430.

The detection unit 3430 includes, for example, a transistor Q30. The transistor Q30 is, for example, an emitter-follower. A conduction angle of the transistor Q30 is adjusted based on a reference voltage Vref2. The transistor Q30 smooths, using a capacitor not illustrated in the drawing, a high frequency component of a signal outputted from the DC removal unit 3420 into DC.

A base of the transistor Q30 is electrically connected to the second terminal of the capacitor C20 of the DC removal unit 3420. A collector of the transistor Q30 is electrically connected to a power supply Vcc. An emitter of the transistor Q30 is electrically connected to the detection terminal 3402. Furthermore, the base of the transistor Q30 is electrically connected to the reference voltage Vref2 with a resistor R30 interposed therebetween. The emitter of the transistor Q30 is electrically connected to a constant current source I1.

Next, an overview of an operation of the drive-level detection circuit 34 will be described.

The collector of the carrier amplifier 13 whose emitter is grounded is electrically connected to the drive-level detection circuit 34. In this case, the instantaneous minimum voltage of the collector of the carrier amplifier 13 decreases (approaches 0 V) as the carrier amplifier 13 approaches saturation. That is, the drive-level detection circuit 34 is in an electrically connected state when the voltage (signal level) of the high frequency signal RF3 inputted to the input terminal 3401 is lower than the reference voltage Vref1.

The range of angles representing the period of the electrically connected state is expressed as a conduction angle. The conduction angle increases as the size of the high frequency signal RF3 increases. A DC component of an output signal outputted from the comparison unit 3410 also increases as the conduction angle increases. In the drive-level detection circuit 34, the DC removal unit 3420 removes the DC component.

In the drive-level detection circuit 34, the detection unit 3430 including an emitter-follower is used. Thus, since the input impedance of the detection unit 3430 is high, the input current to the detection unit 3430 may be small. Since the input impedance of the detection unit 3430 is high, the high frequency signal RF3 does not directly affect the DC component of the signal S1 although the high frequency signal RF3 functions to operate the emitter-follower. That is, in the drive-level detection circuit 34, due to the detection unit 3430 including the emitter-follower, interaction in an AC manner between the comparison unit 3410 and the detection unit 3430 can be suppressed (AC input impedance is increased).

This means that even if the AC output impedance of the comparison unit 3410 is high, the interaction in the AC manner with the detection unit 3430 can be suppressed. For example, in the case where the AC output impedance of the comparison unit 3410 is high and the AC input impedance of the detection unit 3430 is low, when the detection unit 3430 starts operating, the input impedance of the comparison unit 3410 typically drops. That is, although typically the AC output of the comparison unit 3410 is unstable, the AC output of the comparison unit 3410 is stabilized in the drive-level detection circuit 34 by increasing the input impedance by using the emitter-follower for the detection unit 3430.

Although the comparison unit 3410 that includes a transistor whose base is grounded is illustrated in FIG. 3, the comparison unit 3410 is not necessarily configured as illustrated in FIG. 3. For example, the comparison unit 3410 may include a transistor whose emitter is grounded. That is, the comparison unit 3410 may be a comparator that compares the voltage of the collector of the transistor with the voltage of the base of the transistor.

Specifically, in the comparison unit 3410, the function of the comparator is implemented by using a phenomenon in which the base current increases when the potential of the collector drops to be lower than the potential of the base by the base-emitter voltage Vbe or more. That is, the comparison unit 3410 may be configured to cause the base of the transistor to be biased to the base-emitter voltage Vbe and cause the base current to flow when the potential of the collector approaches “0”.

In this case, the emitter of the transistor of the comparison unit 3410 is electrically connected to the ground. The collector of the comparison unit 3410 is electrically connected to the collector (output terminal) of the carrier amplifier 13. The base of the comparison unit 3410 is electrically connected to the reference voltage Vref1 and is also electrically connected to the first terminal of the DC removal unit 3420.

As described above, with the use of the emitter-grounded transistor for the comparison unit 3410, breakdown of the transistor can be suppressed compared to the case where a base-grounded transistor is used. This is because in the case where an emitter-grounded transistor is used, a large voltage is not applied to between the base and emitter thereof, unlike the case where a base-grounded transistor is used in which a large voltage is applied to between the base and emitter thereof.

### (Operation)

Referring back to FIG. 1, in the Doherty amplifier circuit 1 according to the first embodiment, the input signal RFin, which is a high frequency signal inputted to the input terminal Tin, is inputted to the 90-degree hybrid circuit 11 and to the detection circuit 32. The 90-degree hybrid circuit 11 divides the input signal RFin into the high frequency signal RF1 and the high frequency signal RF4 with a phase difference of approximately 90 degrees.

The high frequency signal RF1 outputted from the 90-degree hybrid circuit 11 is inputted to the driver-stage carrier amplifier 12. The carrier amplifier 12 amplifies the high frequency signal RF1 and outputs the signal as the high frequency signal RF2. The high frequency signal RF2 is inputted to the power-stage carrier amplifier 13. The power-stage carrier amplifier 13 amplifies the high frequency signal RF2 and outputs the signal as the high frequency signal RF3. The high frequency signal RF3 is inputted to the coupler 20 and to the drive-level detection circuit 34.

The drive-level detection circuit 34 detects, based on the high frequency signal RF3, the drive level (operation level) of the carrier amplifier 13. The drive-level detection circuit 34 generates the signal S1 indicating the drive level. The signal S1 is inputted to the bias circuit 18-1.

Furthermore, the high frequency signal RF4 outputted from the 90-degree hybrid circuit 11 is inputted to the driver-stage peak amplifier 16. The peak amplifier 16 operates based on the bias supplied from the bias circuit 18-1 and the bias supplied from the bias circuit 18-2. The bias supplied from the bias circuit 18-1 is a bias based on the signal S1. The bias supplied from the bias circuit 18-2 is a bias based on the signal S2 outputted from the detection circuit 32. As described above, in this example, the driver stage is divided into two amplifiers (the first amplifier 16-1 and the second amplifier 16-2), and biases of the two amplifiers can be set by individual bias circuits. That is, individual biases are set by inputting the signal S1 indicating the drive level to the bias circuit 18-1 and inputting the signal S2 corresponding to the strength of the input signal to the bias circuit 18-2.

The peak amplifier 16 amplifies the high frequency signal RF4 and outputs the signal as the high frequency signal RF5. The high frequency signal RF5 is inputted to the power-stage peak amplifier 17. The power-stage peak amplifier 17 amplifies the high frequency signal RF5 and outputs the signal as the high frequency signal RF6. The high frequency signal RF6 is inputted to the coupler 20. The coupler 20 combines the high frequency signal RF3 and the high frequency signal RF6 together. The coupler 20 outputs, as the output signal RFout, which is a high frequency signal, the sum of the high frequency signal RF3 whose phase has been delayed by 90 degrees and the high frequency signal RF6. The output signal RFout is outputted from the output terminal Tout.

As described above, the peak amplifier 16 operates following both the signal S1 indicating the drive level and the signal S2 (baseband signal) corresponding to the strength of the input signal RFin.

With the configuration described above, the peak amplifier 16 can operate following both the signal S1 indicating the drive level and another signal (input signal strength) quickly without requiring an adder in a baseband. Consequently, a Doherty amplifier that quickly amplifies a modulated signal can be attained.

With the configuration in this embodiment, instead of directly adding the two signals S1 and S2, high frequency signals corresponding to the two signals S1 and S2 are generated and added. Regarding the addition of high frequency signals, although an accuracy level that is sufficient to handle the phase difference between the two signals S1 and S2 is required, since a passive circuit can be used, a high-speed operation can be achieved.

In this embodiment, there are two amplifier stages: the peak amplifier 16 (driver stage) and the peak amplifier 17 (power stage). However, three or more amplifier stages may be provided. One or more amplifier stages on a path branching out for a signal to be inputted to a peak amplifier may be divided into two amplifiers, and individual biases may be set for the amplifiers by bias circuits.

### (Effects)

In the Doherty amplifier circuit 1 according to the first embodiment, the peak amplifier 16 is activated following both the signal S1 indicating the drive level and a baseband signal (specifically, the signal S2 corresponding to the strength of the input signal RFin). Thus, unlike U.S. Patent Application Publication No. 2020/0028472, a Doherty amplifier circuit that is capable of following a change speed of a high frequency signal without an adder and supporting high-speed communication can be attained.

### Second Embodiment

### (Configuration)

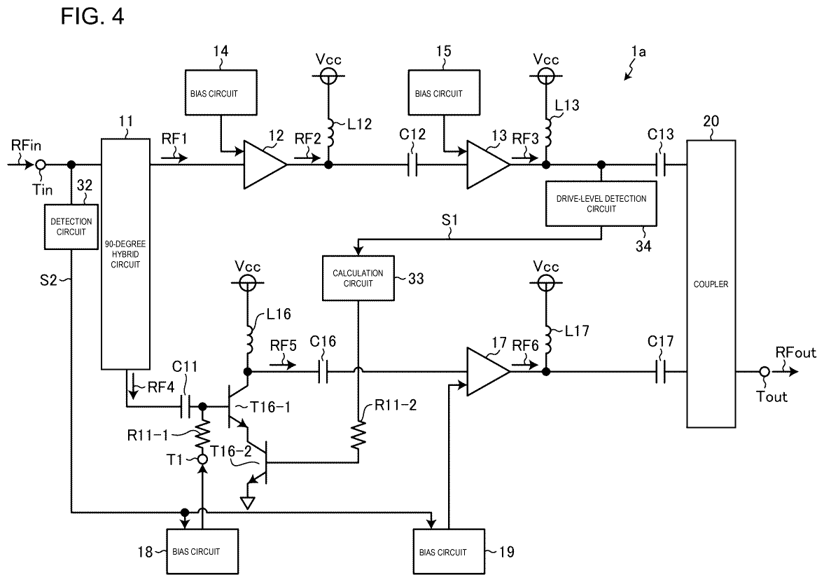

FIG. 4 is a diagram illustrating a configuration of a Doherty amplifier circuit according to a second embodiment. In FIG. 4, a Doherty amplifier circuit 1a according to the second embodiment includes a transistor T16-1 corresponding to a first amplifier and a transistor T16-2 corresponding to a second amplifier, unlike the Doherty amplifier circuit 1 according to the first embodiment described above with reference to FIG. 1.

The transistor T16-1 and the transistor T16-2 are cascode-connected. That is, as illustrated in FIG. 4, an emitter of the transistor T16-1 and a collector of the transistor T16-2 are connected to each other. In FIG. 4, an upper transistor in the cascode connection is the transistor T16-1, and a lower transistor in the cascode connection is the transistor T16-2.

The high frequency signal RF4 outputted from the 90-degree hybrid circuit 11 is inputted through a capacitor C11 to a base of the transistor T16-1. A power supply Vcc is connected to a collector of the transistor T16-1 with the inductor L16 interposed therebetween.

The signal S1 outputted from the drive-level detection circuit 34 is inputted through a calculation circuit 33 and a resistor R11-2 to a base of the transistor T16-2. An emitter of the transistor T16-2 is connected to a reference potential. The reference potential is illustrated as a ground potential. However, the reference potential is not necessarily the ground potential in the present disclosure. The high frequency signal RF4 is not inputted to the transistor T16-2. The state in which “the high frequency signal RF4 is not inputted” represents, specifically, a state in which a wire branching out from a wire serving as a path through which the high frequency signal RF4 is transmitted is not electrically connected to the transistor T16-2 (for example, the base of the transistor T16-2). That is, the state in which “the high frequency signal RF4 is not inputted” represents the state in which a wire serving as a path through which the high frequency signal RF4 is transmitted is not physically connected to the transistor T16-2. This state includes a case where part of the high frequency signal RF4 inevitably enters the transistor T16-2 not through a wire but through a parasitic component of the wire or a parasitic component of an element.

A bias circuit 18 corresponds to the bias circuit 18-2 in FIG. 1. The bias circuit 18 outputs, based on the signal S2, a bias to be supplied to the transistor T16-1. The bias outputted from the bias circuit 18 is applied to a terminal T1. The bias applied to the terminal T1 is inputted through a resistor R11-1 to the base of the transistor T16-1. Furthermore, a bias circuit 19 also outputs, based on the signal S2, a bias to be supplied to the peak amplifier 17.

Furthermore, the signal S1 outputted from the drive-level detection circuit 34 is applied through the calculation circuit 33 and the resistor R11-2 to the base of the transistor T16-2. An output from the calculation circuit 33 is supplied as a bias to the transistor T16-2. The calculation circuit 33 may be configured to invert the signal S1 and output the inverted signal or may be configured to output the signal S1 directly.

A path for peak amplifiers (peak amplifiers 16 and 17) includes a plurality of stages, and an amplifier stage (peak amplifier 16) preceding the final stage (peak amplifier 17) includes two transistors (transistors T16-1 and T16-2). Of the two transistors, an emitter of a transistor (transistor T16-1) is connected to a collector of a transistor (transistor T16-2) whose emitter is connected to the reference potential. Then, the high frequency signal RF5 is outputted from the collector of the upper transistor (transistor T16-1).

Regarding the upper transistor T16-1, the bias is controlled based on the signal S2 outputted from the detection circuit 32. The high frequency signal RF4 is inputted to the base of the upper transistor T16-1. Regarding the lower transistor T16-2, the bias is controlled based on the signal S1 outputted from the drive-level detection circuit 34.

In FIG. 4, each transistor is a bipolar transistor. However, the transistor is not necessarily a bipolar transistor in the present disclosure. The bipolar transistor is illustrated as a heterojunction bipolar transistor (HBT). However, the bipolar transistor is not necessarily an HBT in the present disclosure. The transistor may be, for example, a field effect transistor (FET). The transistor may be a multi-finger transistor including a plurality of unit transistors that are electrically connected in parallel. A unit transistor represents the minimum configuration of a transistor. The same applies to each transistor described below.

Furthermore, in the case where each transistor is an FET, a source corresponds to an emitter of a bipolar transistor, a gate corresponds to a base of the bipolar transistor, and a drain corresponds to a collector of the bipolar transistor. The same applies to each transistor described below.

### (Operation)

With the configuration illustrated in FIG. 4, the product of two signals is implemented by a baseband signal. Specifically, even in the case where the strength of the input signal RFin is sufficiently high and the bias circuit 18 operates in such a manner that bias setting to Class A is performed on the upper transistor T16-1, if bias setting to Class C is performed on the lower transistor T16-2, a collector current of the lower transistor T16-2, that is, a collector current of the upper transistor T16-1, does not flow, and an amplifying operation of the upper transistor T16-1 is not achieved. That is, to achieve an amplifying operation, both the transistors T16-1 and T16-2 need to be ON at the same time. As described above, with the configuration illustrated in FIG. 4, it can be regarded that the operation state of the peak amplifier 16 is controlled based on the product of the two signals S1 and S2. With this configuration, for example, by performing bias setting on the lower transistor T16-2 in such a manner that the transistor T16-2 approaches Class AB when the drive level of the carrier amplifier 13 is low and the transistor T16-2 approaches Class A when the drive level of the carrier amplifier 13 is high, a high-speed operation following both the signal S1 indicating the drive level and a baseband signal (specifically, the signal S2 corresponding to the strength of the input signal RFin) can be expected even without using an adder.

In FIG. 4, similar effects can also be achieved with a configuration in which a high frequency signal is inputted to the base of the lower transistor T16-2, not the upper transistor T16-1. Furthermore, by inputting high frequency signals to both the base of the upper transistor T16-1 and the base of the lower transistor T16-2, a result of addition of the two signals can be obtained in terms of high frequency signals. Thus, an addition result can be obtained more quickly.

Furthermore, in FIG. 4, bias setting based on the signal S2 is performed on the peak amplifier 17 as well as on the transistors T16-1 and T16-2 that configure the peak amplifier 16. Thus, since activation of the power-stage peak amplifier 17 can also be controlled based on the strength of the input signal RFin, an amplifying operation with less distortion can be achieved.

### (Effects)

According to this embodiment, a Doherty amplifier circuit that is capable of following a change speed of a signal and supporting high-speed communication can be attained.

### Third Embodiment

### (Configuration)

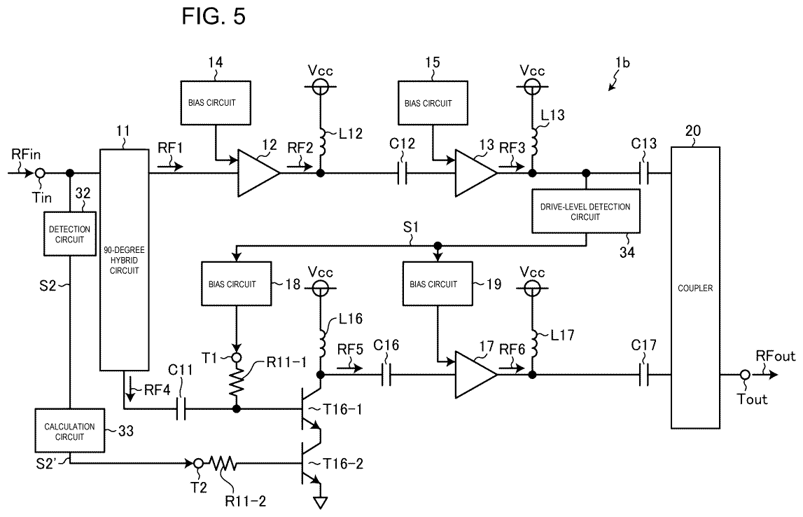

FIG. 5 is a diagram illustrating a configuration of a Doherty amplifier circuit according to a third embodiment. In FIG. 5, a Doherty amplifier circuit 1b according to the third embodiment has a configuration in which a signal to be supplied as a bias to the upper transistor T16-1 and a signal to be supplied as a bias to the lower transistor T16-2 are exchanged in the Doherty amplifier circuit 1a according to the second embodiment.

### (Operation)

Regarding the upper transistor T16-1, the bias is controlled based on the input signal strength (the signal S1 outputted from the drive-level detection circuit 34). The high frequency signal RF4 is inputted to the base of the upper transistor T16-1.

Regarding the lower transistor T16-2, the bias is controlled as described below. That is, the signal S2 outputted from the detection circuit 32 is inputted to the calculation circuit 33. The calculation circuit 33 outputs a signal S2′ based on the signal S2. The signal S2′ is, for example, a signal obtained by performing, on the signal S2, amplification, inversion, level shifting, upper and lower limiting (limiting), or combined processing including some of the processes mentioned above. The signal S2′ is applied to a terminal T2 and is applied as a bias through the resistor R11-2 to the base of the transistor T16-2. As described above, regarding the transistor T16-2, the bias is controlled based on the signal S2 outputted from the detection circuit 32.

### (Effects)

As in the second embodiment, an addition result can be obtained more quickly even without using an adder. Thus, a Doherty amplifier circuit that is capable of following a change speed of a signal and supporting high-speed communication can be attained.

### Fourth Embodiment

### (Configuration)

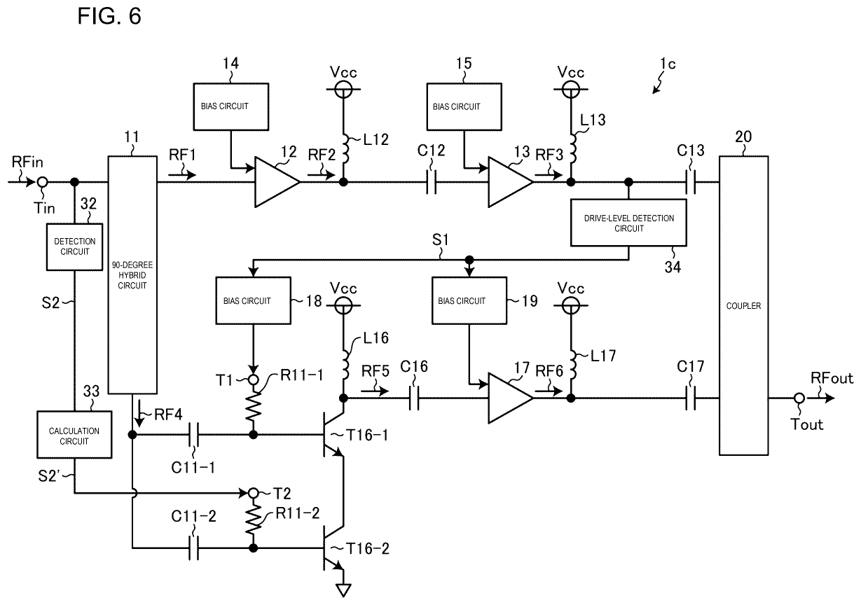

FIG. 6 is a diagram illustrating a configuration of a Doherty amplifier circuit according to a fourth embodiment. In FIG. 6, a Doherty amplifier circuit 1c according to the fourth embodiment has a configuration in which the high frequency signal RF4 is also inputted to the base of the lower transistor T16-2 in the Doherty amplifier circuit 1b according to the third embodiment described above with reference to FIG. 5. That is, the high frequency signal RF4 is inputted through a capacitor C11-1 to the base of the transistor T16-1 and is also inputted through a capacitor C11-2 to the base of the transistor T16-2.

The signal S2 outputted from the detection circuit 32 is inputted to the calculation circuit 33. The calculation circuit 33 outputs the signal S2′ based on the signal S2. The signal S2′ is, for example, a signal obtained by inverting the signal S2. The signal S2′ is applied to the terminal T2 and is supplied as a bias through the resistor R11-2 to the base of the transistor T16-2.

### (Operation)

Regarding the upper transistor T16-1, the bias is controlled based on the input signal strength (the signal S1 outputted from the drive-level detection circuit 34). Regarding the lower transistor T16-2, the bias is controlled based on the signal S2 outputted from the detection circuit 32.

As in the second embodiment, by inputting the high frequency signal RF4 not only to the upper transistor T16-1 but also to the transistor T16-2, the high frequency signal RF5 is obtained as a result of addition of the two signals in terms of high frequency signals.

### (Effects)

As in the second embodiment, an addition result can be obtained more quickly even without using an adder. Furthermore, a quicker circuit response can be achieved compared to the third embodiment. Thus, a Doherty amplifier circuit that is capable of following a change speed of a signal and supporting high-speed communication can be attained.

### Fifth Embodiment

### (Configuration)

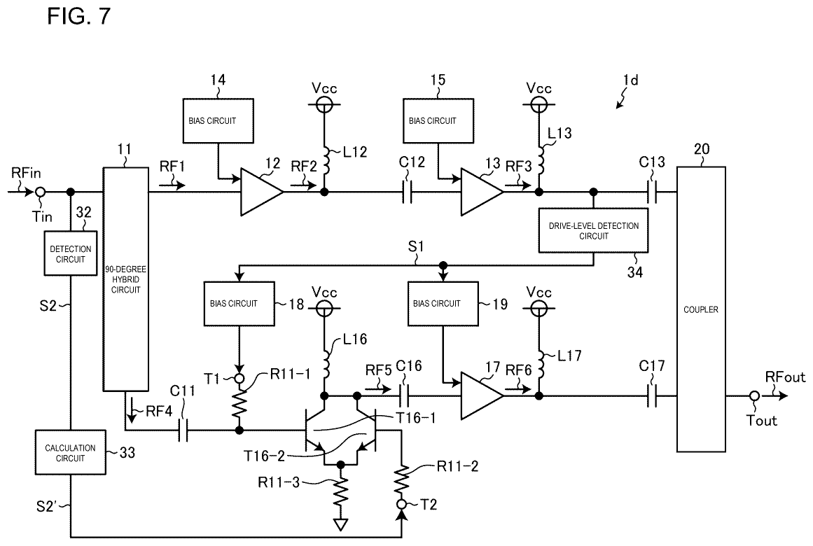

FIG. 7 is a diagram illustrating a configuration of a Doherty amplifier circuit according to a fifth embodiment. In FIG. 7, a Doherty amplifier circuit 1d according to the fifth embodiment includes transistors T16-1 and T16-2 that configure a driver-stage amplifier and a resistor R11-3.

In the Doherty amplifier circuit 1d, an amplifier stage preceding the final-stage peak amplifier 17 on a path for peak amplifiers includes the two transistors T16-1 and T16-2. Emitters of the transistors T16-1 and T16-2 are connected to each other. The emitters of the transistors T16-1 and T16-2 are connected to a reference potential with the resistor R11-3 interposed therebetween.

The bias circuit 18 for setting a bias point based on the signal S1 corresponding to the drive level is connected to the base of the transistor T16-1. In contrast, the calculation circuit 33 is connected to the base of the transistor T16-2 with the terminal T2 and the resistor R11-2 interposed therebetween.

The high frequency signal RF4 outputted from the 90-degree hybrid circuit 11 is inputted through the capacitor C11 to the base of the transistor T16-1. In contrast, the signal S2 outputted from the detection circuit 32, to which the input signal RFin is inputted, is inputted to the calculation circuit 33. The signal S2′ outputted from the calculation circuit 33 is applied to the terminal T2. The output signal S2′ is a signal for setting a bias point based on the input signal strength. The signal S2′ is inputted through the resistor R11-2 to the base of the transistor T16-2.

A bias is supplied from the bias circuit 18, which is for setting a bias point based on the signal S1 indicating the drive level, through the resistor R11-1 to the base of the transistor T16-1. The signal S2′, which is for setting a bias point based on a signal corresponding to the input signal RFin, is supplied through the resistor R11-2 to the base of the transistor T16-2.

Collectors of the transistors T16-1 and T16-2 are connected to each other. The high frequency signal RF5 is outputted from a connection point between the collectors of the transistors T16-1 and T16-2.

### (Operation)

As illustrated in FIG. 7, regarding the transistor T16-1 on a side to which the high frequency signal RF4 is inputted, the bias point is controlled based on the signal S1 indicating the drive level. Regarding the transistor T16-2, the bias point is controlled based on the signal S2′ based on the input signal strength.

However, the transistor T16-2 is controlled in such a manner that the bias point drops when the strength of the input signal RFin is high. By doing this, no emitter current flows in the transistor T16-2 when the strength of the input signal RFin is high, and the emitter current of the transistor T16-2 flows when the strength of the input signal RFin is low. Since the emitter current of the transistor T16-2 flows to the resistor R11-3 to which the transistor T16-2 is connected, a voltage drop occurs. Therefore, as a result, the emitter current of the transistor T16-2 causes the emitter potential of the transistor T16-1 to fluctuate. Furthermore, since the base bias of the transistor T16-1 varies depending on the signal S1 indicating the drive level, the base-emitter voltage of the transistor T16-1 is controlled based on both the input signal strength and the signal S2′ based on the input signal strength. As a result, the Doherty amplifier circuit 1d performs an additive operation of the two signals. A high-speed operation can be achieved by causing the amplifier stage to also execute an adding function, without requiring an adder to be provided as in U.S. Patent Application Publication No. 2020/0028472.

Furthermore, in the case where an adder is used as in U.S. Patent Application Publication No. 2020/0028472, interaction between component elements (a drive-level detection circuit and a supply moderator) that are connected to an input of the adder may cause a malfunction. In contrast, with the configuration in this embodiment, since the two transistors T16-1 and T16-2 are sandwiched between two component elements, mutual interference is less likely to occur.

By connecting a capacitor (not illustrated in the drawing) in parallel to the resistor connected to the emitters of the transistors T16-1 and T16-2, the amount of gain change of the amplifier stage can be increased.

### (Effects)

According to the fifth embodiment, an addition result can be obtained more quickly even without using an adder. Thus, a Doherty amplifier circuit that is capable of following a change speed of a signal and supporting high-speed communication can be attained.

### Sixth Embodiment

### (Configuration)

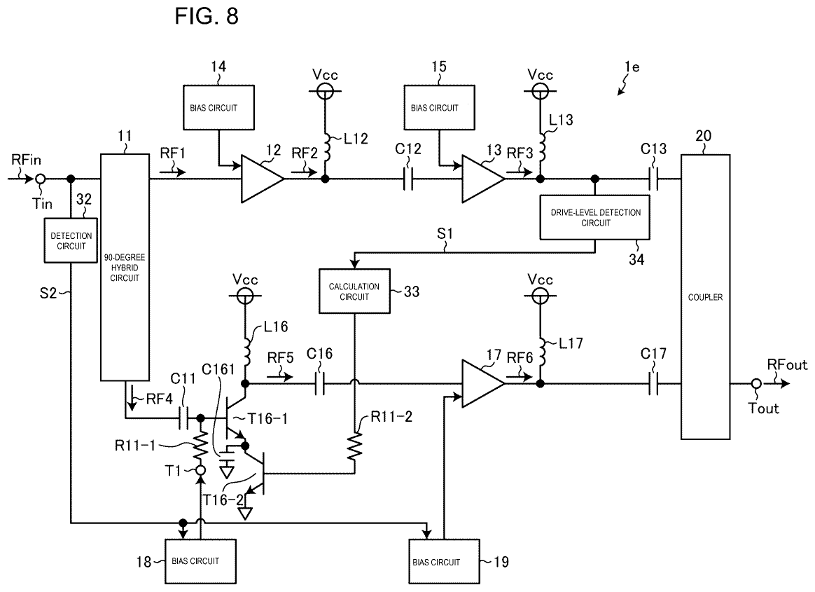

FIG. 8 is a diagram illustrating a configuration of a Doherty amplifier circuit according to a sixth embodiment. In FIG. 8, a Doherty amplifier circuit 1e according to the sixth embodiment has a configuration in which a capacitor C161 is added to the Doherty amplifier circuit 1a described above with reference to FIG. 4. One end of the capacitor C161 is connected to a connection point between the emitter of the transistor T16-1 and the collector of the transistor T16-2. The other end of the capacitor C161 is connected to a reference potential. That is, the capacitor C161 is connected between the connection point between the transistor T16-1 and the transistor T16-2 and the reference potential.

### (Operation)

By connection with the capacitor C161, an impedance on the emitter terminal side of the transistor T16-1 can be reduced.

### (Effects)

Since the impedance on the emitter terminal side of the transistor T16-1 can be reduced, a Doherty amplifier circuit that is capable of following a change speed of a signal and supporting high-speed communication can be attained. Excellent grounding characteristics of the transistor T16-1 can be achieved, and a large amount of gain change can be achieved.

### Seventh Embodiment

### (Configuration)

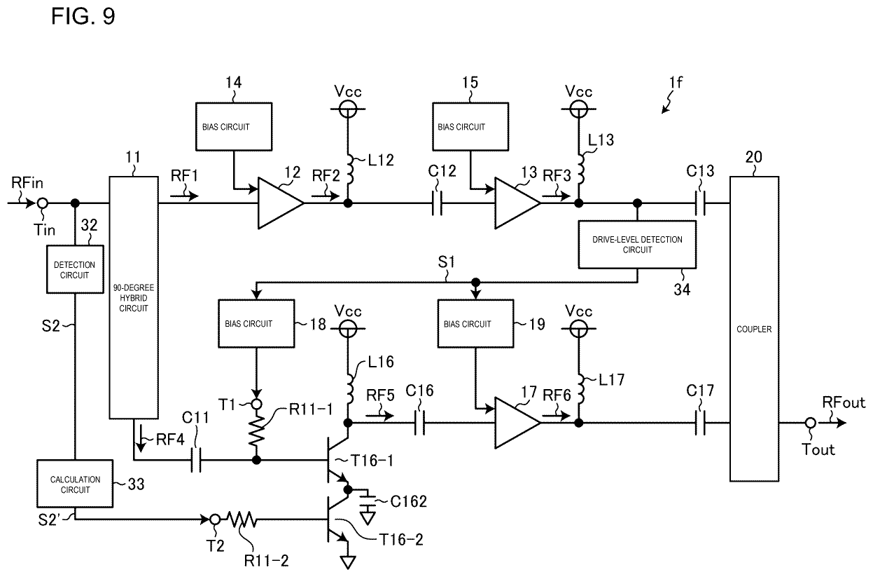

FIG. 9 is a diagram illustrating a configuration of a Doherty amplifier circuit according to a seventh embodiment. In FIG. 9, a Doherty amplifier circuit 1f according to the seventh embodiment has a configuration in which a capacitor C162 is added to the Doherty amplifier circuit 1b described above with reference to FIG. 5. One end of the capacitor C162 is connected to a connection point between the emitter of the transistor T16-1 and the collector of the transistor T16-2. The other end of the capacitor C162 is connected to a reference potential.

### (Operation)

By connection with the capacitor C162, the impedance on the emitter terminal side of the transistor T16-1 can be reduced.

### (Effects)

Since the impedance on the emitter terminal side of the transistor T16-1 can be reduced, a Doherty amplifier circuit that is capable of following a change speed of a signal and supporting high-speed communication can be attained. Excellent grounding characteristics of the transistor T16-1 can be achieved, and a large amount of gain change can be achieved.
1, 1a to 1f Doherty amplifier circuit
11 90-degree hybrid circuit
12, 13 carrier amplifier
14, 15, 18, 18-1, 18-2, 19 bias circuit
16, 17 peak amplifier
16-1 first amplifier
16-2 second amplifier
20 coupler
32 detection circuit
33 calculation circuit
34 drive-level detection circuit
T16-1, T16-2 transistor

1. A Doherty amplifier circuit comprising:
a carrier amplifier configured to amplify a first high frequency signal corresponding to an input high frequency signal;
a driver-stage peak amplifier configured to amplify a second high frequency signal having a predetermined phase relationship with a phase of the first high frequency signal;
a power-stage peak amplifier configured to receive an output from the driver-stage peak amplifier; and
a drive-level detection circuit configured to detect a drive level of the carrier amplifier,
wherein the driver-stage peak amplifier comprises a first amplifier and a second amplifier,
wherein a bias based on a drive level signal indicating the drive level detected by the drive-level detection circuit is supplied to one of the first amplifier and the second amplifier, and
wherein a bias corresponding to the input high frequency is supplied to the other one of the first amplifier and the second amplifier.

2. The Doherty amplifier circuit according to claim 1,
wherein the first amplifier and the second amplifier are connected in parallel, and
wherein the second high frequency signal is input to the first amplifier and the second amplifier.

3. The Doherty amplifier circuit according to claim 1,
wherein the first amplifier comprises a first transistor,
wherein the second amplifier comprises a second transistor,
wherein the first transistor and the second transistor are cascode-connected, and
wherein the second high frequency signal is input to the first transistor or the second transistor.

4. The Doherty amplifier circuit according to claim 3,
wherein the second high frequency signal is input to one of the first transistor and the second transistor, and
wherein the second high frequency signal is not input to the other one of the first transistor and the second transistor.

5. The Doherty amplifier circuit according to claim 3, wherein the second high frequency signal is input to both the first transistor and the second transistor.

6. The Doherty amplifier circuit according to claim 4, further comprising:
a capacitor that is connected between a reference potential and a node between the first transistor and the second transistor.

7. The Doherty amplifier circuit according to claim 1,
wherein the first amplifier comprises a first transistor,
wherein the second amplifier comprises a second transistor,
wherein an emitter or a source of the first transistor is connected to a reference potential and to an emitter or a source of the second transistor, and a collector or a drain of the first transistor is connected to a collector or a drain of the second transistor,
wherein the second high frequency signal is input to one of a base or a gate of the first transistor and a base or a gate of the second transistor, and
wherein the second high frequency signal is not input to the other one of the base or the gate of the first transistor and the base or the gate of the second transistor.
